(19) United States
(12) Patent Application Publication
(10) Pub. No.: US 2026/0013119 A1
(43) Pub. Date: Jan. 8, 2026

(54) THREE DIMENSIONAL INTEGRATED CIRCUIT MEMORY DEVICES HAVING ENHANCED SUB-WORD LINE DRIVERS THEREIN AND METHODS OF OPERATING SAME

(71) Applicant: Samsung Electronics Co., Ltd., Suwon-si (KR)

(72) Inventors: Eunsuk JANG, Suwon-si (KR); Jinwoo HAN, Suwon-si (KR)

(21) Appl. No.: 19/173,098

(22) Filed: Apr. 8, 2025

(30) Foreign Application Priority Data
Jul. 3, 2024 (KR) 10-2024-0087355

(51) Int. Cl. H10B 12/00; G11C 11/408; H01L 23/00; H01L 25/065; H01L 25/18; H10B 80/00

(52) U.S. Cl. CPC H10B 12/50; G11C 11/4085; H01L 24/08; H01L 25/0657; H01L 25/18; H10B 80/00; H01L 2224/08145; H01L 2924/1431; H01L 2924/1436

(57) ABSTRACT

A three-dimensional integrated circuit memory device includes a substrate having layers vertically stacked thereon; the layers include: memory cells horizontally arranged to form one row, a word line electrically connected to the plurality of memory cells, and an electrode horizontally extending from the word line and forming a stair structure with other electrodes associated with respective ones of the plurality of layers. Vertically-extending contacts are provided, which electrically contact corresponding electrodes in an open area of each of the layers. A first sub-word line driver has a first driving characteristic and is electrically connected through a first one of the vertically-extending contacts to an electrode associated with a first layer layers. A second sub-word line driver has a second driving characteristic different from the first driving characteristic and is electrically connected through a second one of the vertically-extending contacts to an electrode associated with a second layer among the layers.

### REFERENCE TO PRIORITY APPLICATION

This application claims priority under 35 U.S.C. § 119 to Korean Patent Application No. 10-2024-0087355, filed Jul. 3, 2024, the disclosure of which is hereby incorporated herein by reference.

### BACKGROUND

Embodiments of the present disclosure relate to an integrated circuit memory device and, more particularly, to a three-dimensional integrated circuit memory device including word lines having different characteristics.

To satisfy excellent performance and low prices, which the consumer requires, an increase in the degree of integration of a semiconductor device is required. In the case of an integrated circuit memory device, because the degree of integration thereof acts as an important factor determining the price of a product, in particular, the increased degree of integration is required. In a conventional two-dimensional or planar semiconductor device, because the degree of integration thereof is mainly determined by the area occupied by the unit memory cell, the degree of integration has a great influence of the level of a fine pattern forming technology. However, because very expensive equipment is required to form a fine pattern, there is a limitation on increasing the degree of integration of a two-dimensional semiconductor device. For this reason, a three-dimensional integrated circuit memory device that utilizes memory cells arranged in a three-dimensional manner is proposed.

According to the structure of the three-dimensional memory device, a plurality of layers may be vertically stacked on a substrate, and elements extending in different layers may have different electrical characteristics. Operating speeds of these elements may be different due to different electrical characteristics of the memory elements in the respective layers, thereby causing the deterioration of performance of the three-dimensional integrated circuit memory device. Accordingly, there is required a method for improving the performance of the three-dimensional integrated circuit memory device.

### SUMMARY

Embodiments of the present disclosure provide a three-dimensional integrated circuit memory device maintaining performance independently of different electrical characteristics of respective word lines vertically stacked.

According to an embodiment, a three-dimensional memory device may include a plurality of layers vertically stacked on a substrate. Each of the plurality of layers may include memory cells horizontally arranged to form one row, a word line connected to the memory cells, and an electrode horizontally extending from the word line and forming a stair structure with electrodes of the remaining electrodes, a plurality of contacts each being in contact with a corresponding electrode in an open area of each of the plurality of layers and vertically extending, a first sub-word line driver connected to the electrode corresponding to a first layer among the plurality of layers through a first contact and having a first driving characteristic, and a second sub-word line driver connected to the electrode corresponding to a second layer among the plurality of layers through a second contact and having a second driving characteristic different from the first driving characteristic.

According to an embodiment, a three-dimensional memory device includes a first substrate, a cell array structure including a plurality of layers vertically stacked on the first substrate, a second substrate bonded to the first substrate, and a peripheral circuit structure disposed on the second substrate and including a plurality of sub-word line drivers driving word lines included in the cell array structure. A first driving characteristic of a first sub-word line driver driving a first layer from among the plurality of sub-word line drivers may be different from a second driving characteristic of a second sub-word line driver driving a second layer from among the plurality of sub-word line drivers.

According to an embodiment, a three-dimensional memory device may include a stacked structure including a plurality of layers vertically stacked. Each of the plurality of layers may include memory cells disposed along a first direction of a horizontal direction and arranged in a second direction of a horizontal direction perpendicular to the first direction to form one row, and a conductive line extending in the second direction, connected to gate terminals of the memory cells belonging to the one row, the conductive lines of the plurality of layers forming a stair structure, a plurality of bit lines extending from one side of the stacked structure in a third direction of a vertical direction and each connected to source terminals of memory cells arranged in the third direction to form one column, an electrode plate disposed on an opposite side of the stacked structure in the shape of a vertical plane and connected to cell capacitors of memory cells included in each of the plurality of layers, a plurality of contacts each being in contact with a corresponding conductive line in an open area of each of the plurality of layers, and a plurality of sub-word line drivers electrically connected to the contacts, and each configured to apply a driving voltage to a corresponding conductive line. A first driving characteristic of a first sub-word line driver corresponding to a first layer among the plurality of layers may be higher than a second driving characteristic of a second sub-word line driver corresponding to a second layer above the first layer.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a three-dimensional integrated circuit memory device according to embodiments of the present disclosure.

FIG. 2 is a circuit diagram illustrating a cell array of a three-dimensional integrated circuit memory device according to an embodiment of the present disclosure.

FIG. 3 is a perspective view illustrating a cell array of a three-dimensional integrated circuit memory device according to an embodiment of the present disclosure.

FIG. 4 is a vertical plan view of a portion of a cell array structure of a three-dimensional integrated circuit memory device according to an embodiment of the present disclosure.

FIG. 5 is a front view of a portion of a stacked structure of a three-dimensional integrated circuit memory device according to an embodiment of the present disclosure.

FIG. 6 is a diagram illustrating a part of a peripheral circuit of a three-dimensional integrated circuit memory device according to an embodiment of the present disclosure.

FIG. 7 is a circuit diagram of sub-word line drivers of a three-dimensional integrated circuit memory device according to an embodiment of the present disclosure.

FIG. 8 is a diagram illustrating an example of pull-up transistors of a sub-word line driver according to an embodiment of the present disclosure.

FIG. 9 is a diagram illustrating word line enable signals and voltages of electrodes of respective layers of a three-dimensional integrated circuit memory device according to an embodiment of the present disclosure.

FIG. 10 is a diagram illustrating stacked conductive lines according to an embodiment of the present disclosure.

FIG. 11 is a perspective view of a three-dimensional integrated circuit memory device according to an embodiment of the present disclosure.

FIG. 12 is a diagram illustrating a wafer bonding structure according to an embodiment of the present disclosure.

### DETAILED DESCRIPTION

Below, embodiments of the present disclosure will be described in detail and clearly to such an extent that one of ordinary skill in the art may easily carry out the present disclosure.

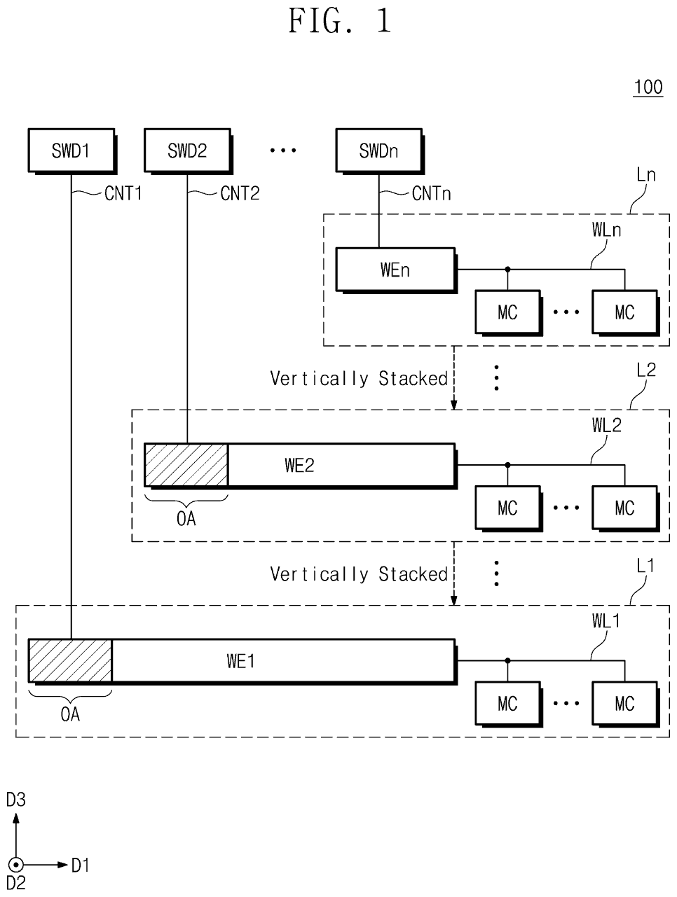

FIG. 1 is a block diagram illustrating a three-dimensional integrated circuit memory device according to embodiments of the present disclosure. Referring to FIG. 1, a three-dimensional integrated circuit memory device 100 may include a plurality of layers L1, L2, . . . , Ln vertically stacked on a substrate. Each of the plurality of layers L1 to Ln may include memory cells MC horizontally disposed at a row level, a word line WL connected to the memory cells, and an electrode WE horizontally extending from a word line and forming a stair structure with electrodes in the remaining layers.

For example, the first layer L1 may include a plurality of memory cells MC. Each of the plurality of memory cells MC may be disposed to face a second direction D2. The plurality of memory cells MC may be arranged in a first direction D1 to form one row. A word line WL1 may extend in the first direction D1 and may connect the memory cells MC included in the first layer L1. An electrode WE1 of the first layer L1 may extend from the word line WL1 in the horizontal direction (e.g., a direction parallel to the first direction D1).

The plurality of memory cells MC may store data. The memory cells MC may include a memory element using a capacitor, a memory element using a magnetic tunnel junction pattern, or a memory element using a variable resistance element including a phase-change material. As an example, the memory cells MC may be implemented with a memory element using a capacitor to store data in a volatile manner.

A plurality of layers may be stacked in a vertical direction. For example, the second layer L2 may be stacked on the first layer L1, such that the first layer L1 extends between the second layer L2 and the underlying substrate. The second layer L2 may be stacked immediately on the first layer L1, or one or more layers may be stacked between the first layer L1 and the second layer L2.

The second layer L2 may include a plurality of memory cells MC facing the second direction D2 and arranged in the first direction D1 to form one row. A word line WL2 may connect the plurality of memory cells MC of the second layer L2. An electrode WE2 of the second layer L2 may extend from the word line WL2 in the direction parallel to the first direction D1.

Each of electrodes WE1 to WEn respectively included in the plurality of layers L1 to Ln may have ends that form a vertical stair structure with adjacent layers, when viewed in cross-section. In other words, the size of an electrode disposed in a relatively lower stair from among the plurality of electrodes WE1 to WEn may be larger than the size of an electrode disposed in a relatively upper stair from among the plurality of electrodes WE1 to WEn. The plurality of layers L1 to Ln may include an open area OA not overlapping a layer of an adjacent upper stair. An electrode in the open area OA may be opened in the vertical direction. The plurality of electrodes WE1 to WEn may have different electrical characteristics depending on the size. For example, the electrode WE1 of the first layer L1 may have a larger loading than electrodes disposed in relatively upper stairs. The electrode WE2 of the second layer L2 may have a relatively small loading compared to the electrode WE1 of the first layer L1. The electrode WEn of the n-th layer Ln may have a relatively small loading compared to the electrode WE2 of the second layer L2. Loading differences of the electrodes WE1 to WEn may cause voltage slope differences and voltage level differences of the electrodes WE1 to WEn.

The three-dimensional integrated circuit memory device 100 may further include a plurality of contacts CNT1, CNT2, . . . , CNTn. The plurality of contacts CNT1 to CNTn may be in contact with the corresponding electrodes WE1 to WEn in the open areas OA. The plurality of contacts CNT1 to CNTn may extend in the vertical direction (e.g., a third direction D3). Signals for driving the plurality of word lines WL1 to WLn respectively may be respectively transferred to the corresponding electrodes WE1 to WEn through the plurality of contacts CNT1 to CNTn.

The three-dimensional integrated circuit memory device 100 may further include a plurality of sub-word line drivers SWD1, SWD2, . . . , SWDTn. The plurality of sub-word line drivers SWD1 to SWDn may respectively apply word line driving signals to the corresponding electrodes WE1 to WEn through the corresponding contacts CNT1 to CNTn.

The plurality of sub-word line drivers SWD1 to SWDn according to an embodiment of the present disclosure may have different driving characteristics. A driving characteristic of a sub-word line driver includes an element associated with an operation of the sub-word line driver, such as a high-level voltage of the word line driving signal, a negative voltage of the sub-word line driver, a physical structure (e.g., a channel width(s) of transistors constituting the sub-word line driver) of the sub-word line driver, and a timing of a word line enable signal.

The first sub-word line driver SWD1 may be connected to the electrode WE1 of the first layer L1 through the first contact CNT1. The first sub-word line driver SWD1 may have a first driving characteristic. The second sub-word line driver SWD2 may be connected to the electrode WE2 of the second layer L2 through the second contact CNT2. The second sub-word line driver SWD2 may have a second driving characteristic different from the first driving characteristic.

The first driving characteristic and the second driving characteristic may be determined in consideration of the electrical characteristic of the electrode WE1 of the first layer L1 and the electrical characteristic of the electrode WE2 of the second layer L2. For example, the electrode WE1 of the first layer L1 corresponding to a relatively lower stair may have a relatively greater loading than the electrode WE2 of the second layer L2 corresponding to a relatively upper stair. The first driving characteristic of the first sub-word line driver SWD1 may be set to be relatively higher (e.g., with more drive capability for a larger load) than the second driving characteristic of the second sub-word line driver SWD2.

As an example, the word line driving voltage that the first sub-word line driver SWD1 applies to the electrode WE1 may be higher than the word line driving voltage that the second sub-word line driver SWD2 applies to the electrode WE2. As another example, the negative voltage at which the first sub-word line driver SWD1 pulls downs from the electrode WE1 may be lower than the negative voltage at which the second sub-word line driver SWD2 pulls down from the electrode WE2. As another example, the width of the channel of transistors constituting the first sub-word line driver SWD1 may be larger than the width of the channel of transistors constituting the second sub-word line driver SWD2 (i.e., to supply more current at a given voltage). As another example, the timing of the word line enable signal applied to the first sub-word line driver SWD1 may be different from the timing of the word line enable signal applied to the second sub-word line driver SWD2. In this case, the timing at which the word line enable signal is applied to the first sub-word line driver SWD1 may be earlier than the timing at which the word line enable signal is applied to the second sub-word line driver SWD2. Thus, according to the above description, the operating speed of the word line WL1 included in the first layer L1 may approximately coincide with the operating speed of the word line WL2 included in the second layer L2, and thus, the performance of the three-dimensional integrated circuit memory device 100 may be maintained, even with drivers having unequal driving characteristics.

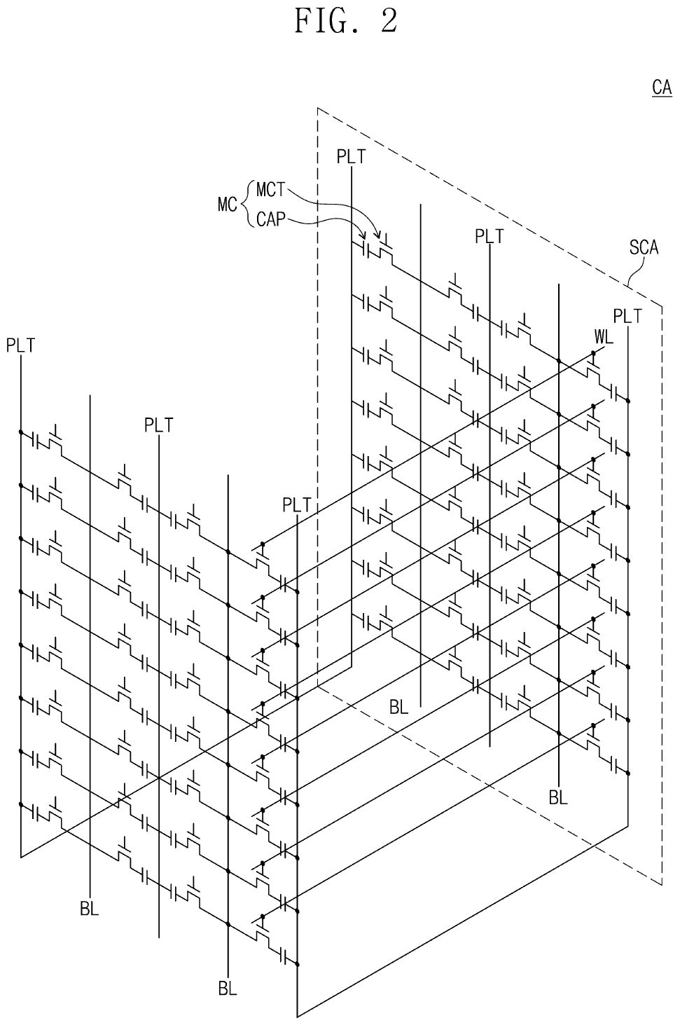

FIG. 2 is a circuit diagram illustrating a cell array of a three-dimensional integrated circuit memory device according to an embodiment of the present disclosure. Referring to FIG. 2, a cell array CA of the three-dimensional integrated circuit memory device 100 may include a plurality of sub-cell arrays SCA. The sub-cell arrays SCA may be arranged along the first direction D1. As shown, each of the sub-cell arrays SCA may include a plurality of bit lines BL, a plurality of word lines WL, and a plurality of memory cells MC. Each of the plurality of memory cells MC may include one memory cell transistor MCT and one cell capacitor CAP (for storing data in a volatile manner (and requiring periodic refresh)).

Each of the bit lines BL may be a conductive line (e.g., a metal line) extending from the substrate in the vertical direction (e.g., the third direction D3). The bit lines BL in one sub-cell array SCA may be arranged in the second direction D2. The bit line BL may be connected to the memory cells MC stacked along the third direction D3. The bit line BL may be connected to source/drain terminals of the memory cell transistors MCT of the memory cells MC.

The word lines WL may be conductive lines stacked on the substrate in the third direction D3. Each word line WL may extend in the first direction D1. Each word line WL may extend in the first direction D1 and may be connected to the memory cells MC of the sub-cell arrays SCA. The word line WL may be connected to a gate terminal included in the memory cell transistor MCT included in the memory cell MC.

A first source/drain terminal of the memory cell transistor MCT may be connected to the bit line BL, the second source/drain terminal thereof may be connected to the cell capacitor CAP, and a gate terminal thereof may be connected to the word line WL. A first electrode of the cell capacitor CAP may be connected to the second source/drain terminal of the memory cell transistor MCT, and a second electrode thereof may be connected to a plate PLT. The second electrodes of the plurality of cell capacitors CAP included in the sub-cell array SCA may be connected in common to the plate PLT.

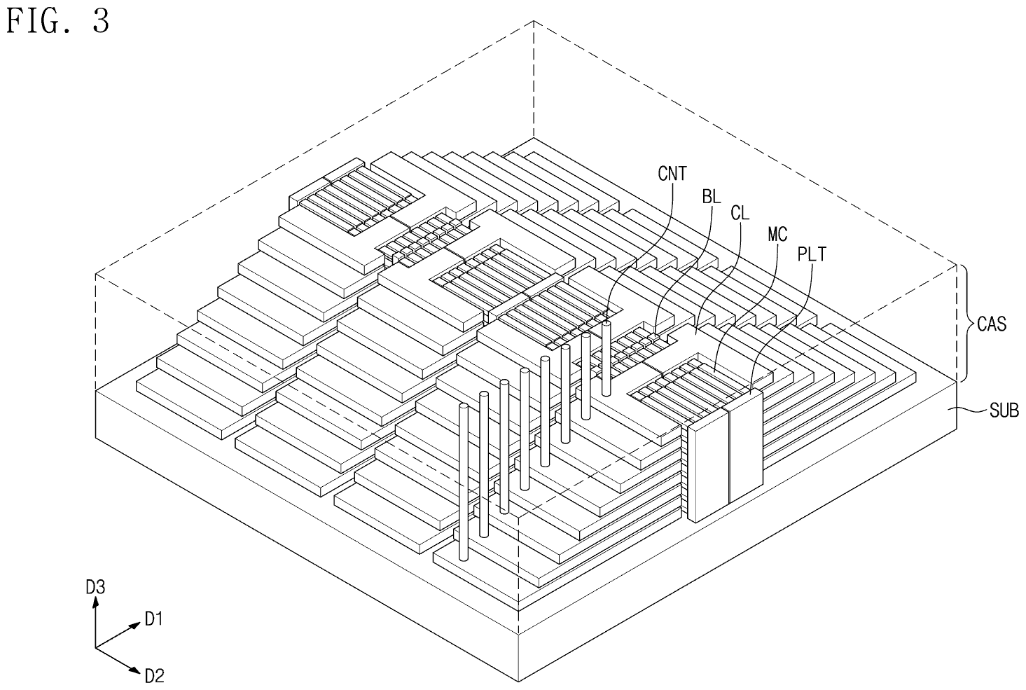

FIG. 3 is a perspective view illustrating a cell array of a three-dimensional integrated circuit memory device according to an embodiment of the present disclosure. Referring to FIG. 3, a cell array structure CAS may be disposed on a substrate SUB. Each component of the cell array structure CAS corresponds to the cell array CA. For example, the memory cell MC, a conductive line CL, and the contact CNT of FIG. 3 correspond to the memory cell MC, the word line WL, and the contact CNT of FIG. 2. The bit line BL and the plate PLT of FIG. 3 correspond to the bit line BL and the plate PLT of FIG. 2.

The conductive lines CL included in the cell array structure CAS are stacked in the third direction D3, and a plurality of layers form a stair structure. Due to the stair structure, the size of the conductive line CL corresponding to a relatively lower stair is relatively larger/longer than the size of the conductive line CL corresponding to a relatively upper stair. This means that conductive lines of relatively lower stairs have a larger effective loading characteristic. Accordingly, when the word line driving voltage is applied to the conductive lines CL through the contacts CNT, voltage reactions of the conductive lines CL may be different depending on the level of the stairs to which the conductive lines CL belong. For example, when the same word line driving signal is applied to the conductive line CL of an upper stair and the conductive line CL of a lower stair, the voltage rising slope of the conductive line CL of the lower stair may be different from the voltage rising slope of the conductive line CL of the upper stair. Also, due to a difference between capacities of the conductive lines CL, final voltage levels of the conductive lines CL may also be different. The electrical characteristic of the conductive line CL, which is differently determined depending on a stair, may cause the deterioration of operation of the three-dimensional integrated circuit memory device 100.

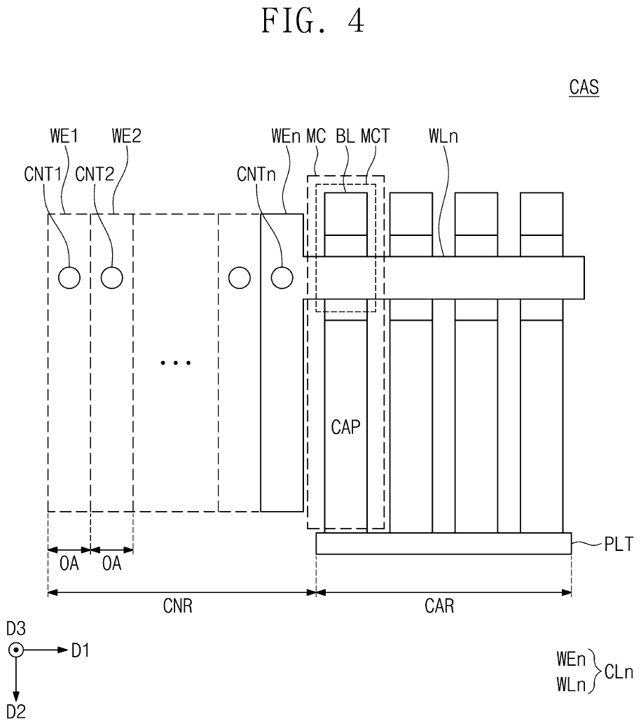

FIG. 4 is a vertical plan view of a portion of a cell array structure of a three-dimensional integrated circuit memory device according to an embodiment of the present disclosure. Referring to FIG. 4, the cell array structure CAS may include a cell array region CAR and a connection region CNR. The plurality of memory cells MC may be disposed in the cell array region CAR to face the second direction D2. Memory cells may be arranged in the first direction D1 to form one row.

The plurality of electrodes WE1, WE2, . . . , WEn form a stair structure in the connection region CNR. The plurality of electrodes WE1 to WEn are in contact with the plurality of contacts CNT1, CNT2, . . . , CNTn. For example, the electrode WE1 is located in the lowest stair, a portion of the electrode WE1 vertically overlaps the electrode WE2, and the remaining portion of the electrode WE1 is opened in the open area OA to face the third direction D3. The electrode WE1 may be in contact with the contact CNT1 in the open area OA of the electrode WE1. The contact CNT1 may vertically extend and may transfer a signal for driving a word line corresponding to the electrode WE1, which is applied from the outside of the cell array structure CAS. Likewise, the electrode WE2 may be in contact with the contact CNT2 in the open area OA of the electrode WE2.

In association with the n-th layer being the highest layer, the plurality of memory cells MC are connected to the word line WLn in the cell array region CAR. The electrode WEn and the word line WLn extends from the connection region CNR in a direction parallel to the first direction D1. The electrode WEn and the word line WLn correspond to the same conductive line CLn.

The memory cell MC may include the memory cell transistor MCT and the cell capacitor CAP. The first source/drain terminal of the memory cell transistor MCT may be connected to the bit line BL. The second source/drain terminal of the memory cell transistor MCT may be connected to the cell capacitor CAP. The gate terminal of the memory cell transistor MCT may be connected to the word line WL. The memory cell transistor MCT may have a planar transistor structure (e.g., a planar FET structure) in which one surface of a channel is in contact with a gate, a transistor structure (e.g., a finFET structure) in which two or more surfaces are in contact with a gate, a structure (e.g., a gate all around (GAA) in which all the surfaces surround a gate, or a multi-bridge channel structure (MBC FET).

The cell capacitor CAP may include a first electrode, a dielectric layer, and a second electrode. The first electrode may be connected to the second source/drain terminal of the memory cell transistor MCT. The second electrode may be connected to the plate PLT. The dielectric layer may provide an insulation between the first electrode and the second electrode. The cell capacitor CAP may store data in the form of charges. Bit “0” or bit “1” may be classified depending on whether charges are stored in the cell capacitor CAP or not.

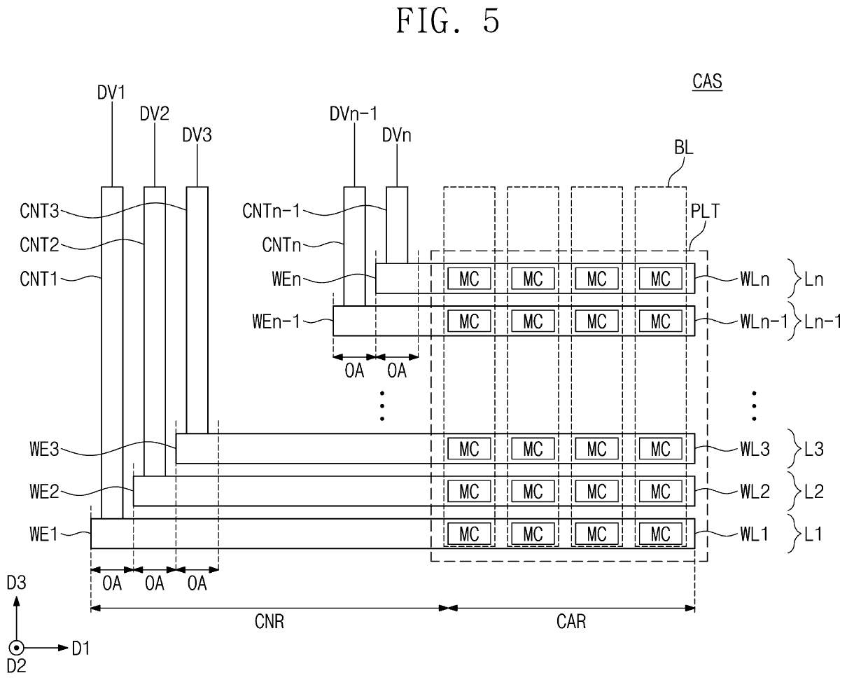

FIG. 5 is a front view of a portion of a stacked structure of a three-dimensional integrated circuit memory device according to an embodiment of the present disclosure. Referring to FIG. 5, the plurality of layers L1, L2, . . . , Ln may be stacked in the third direction D3. In each of the plurality of layers L1 to Ln of the cell array region CAR, the memory cells MC may be arranged in the first direction D1 to form one row. The memory cells MC of each of the plurality of layers L1 to Ln may be connected to the corresponding word lines WL1 to WLn. For example, the memory cells MC of the first layer L1 may be connected to the word line WL1. The memory cells MC of the second layer L2 may be connected to the word line WL2. The memory cells MC of the n-th layer Ln may be connected to the word line WLn.

The plurality of word lines WL1 to WLn may surround the channels of the plurality of memory cells MC. An insulating layer may be provided between the channels of the plurality of memory cells MC corresponding to each of the plurality of word lines WL1 to WLn. The plurality of memory cells MC corresponding to the plurality of word lines WL1 to WLn may be connected in various methods.

In the connection region CNR, the plurality of electrodes WE1 to WEn may extend from the corresponding word lines WL1 to WLn in a direction parallel to the first direction D1. For example, the electrode WE1 may extend from the word line WL1 in a direction parallel to the first direction D1. The electrode WE2 may extend from the word line WL2 in a direction parallel to the first direction D1. The electrode WEn may extend from the word line WEn in a direction parallel to the first direction D1. Each of the word lines WL1 to WLn and each of the corresponding electrodes WE1 to WEn may correspond to the same conductive line.

In the connection region CNR, each of the plurality of electrodes WE1 to WEn may be connected to the corresponding one among the plurality of contacts CNT1 to CNTn. For example, a portion of the electrode WE1 of the first layer L1 may vertically overlap the electrode WE2 of the second layer L2, and the remaining portion thereof may be opened in the third direction D3. The contact CNT1 may be in contact with the electrode WE1 in the open area OA of the electrode WE1 and may extend in the third direction D3. The contact CNT2 may be in contact with the electrode WE2 in the open area OA in which the electrode WE2 does not overlap the electrode WE3 and may extend in the third direction D3. The contact CNTn may be in contact with the electrode WEn in the open area OA of the electrode WEn and may extend in the third direction D3.

Driving voltages DV1 to DVn may be respectively transferred to the corresponding electrodes WE1 to WEn through the plurality of contacts CNT1 to CNTn. For example, the driving voltage DV1 is transferred to the electrode WE1 through the contact CNT1. The driving voltage DV1 of an operation level may activate the memory cells MC of the first layer L1. The driving voltage DV2 is transferred to the electrode WE2 through the contact CNT2. The driving voltage DV2 of an operation level may activate the memory cells MC of the second layer L2.

Loadings of the corresponding electrodes WE1 to WEn may be different depending on the stairs of the plurality of layers L1 to Ln. For example, due to the stair structure which the plurality of electrodes WE1 to WEn form, the loading of the electrode WE1 may be larger than the loading of the electrode WE2. The electrical characteristics of the plurality of electrodes WE1 to WEn may be different. In association with the plurality of layers L1 to Ln, the three-dimensional integrated circuit memory device 100 according to an embodiment of the present disclosure may provide sub-word line drivers with different driving characteristics.

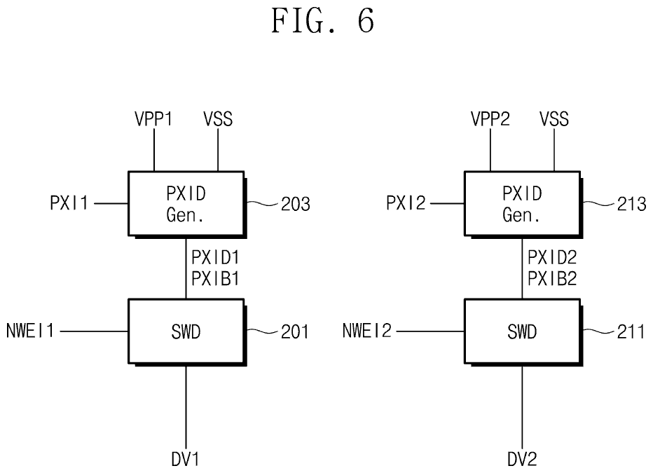

FIG. 6 is a diagram illustrating a part of a peripheral circuit of a three-dimensional integrated circuit memory device according to an embodiment of the present disclosure. Referring to FIG. 6, a peripheral circuit PERI may include a first sub-word line driver 201 and a first word line driving signal generator 203. The peripheral circuit PERI may further include a second sub-word line driver 211 and a second word line driving signal generator 213. The peripheral circuit PERI may be formed in the same substrate as the cell array structure CAS. A substrate where the peripheral circuit PERI is formed may be different from a substrate where the cell array structure CAS is formed.

The first word line driving signal generator 203 may be provided with a first boosting voltage VPP1 and a ground voltage VSS. The first word line driving signal generator 203 may output one of the first boosting voltage VPP1 or the ground voltage VSS as a voltage of a first word line driving signal PXID1, based on a first word line control signal PXI1. The first word line driving signal generator 203 may output a complementary signal PXIB1 of the first word line driving signal PXID1. The first word line driving signal PXID1 and the complementary signal PXIB1 are provided to the first sub-word line driver 201.

The second word line driving signal generator 213 may be provided with a second boosting voltage VPP2 and the ground voltage VSS. The second word line driving signal generator 213 may output one of the second boosting voltage VPP2 or the ground voltage VSS as a voltage of a second word line driving signal PXID2, based on a second word line control signal PX12. The second word line driving signal generator 213 may output a complementary signal PXIB2 of the second word line driving signal PXID2. The second word line driving signal PXID2 and the complementary signal PXIB2 are provided to the second sub-word line driver 211.

The first word line control signal PXI1 and the second word line control signal PXI2 may be used to select and control at least one of a plurality of word lines. The first word line control signal PXI1 and the second word line control signal PX12 may be generated by a row decoder. The first word line control signal PXI1 and the second word line control signal PXI2 may be generated through a separate signal generator configured to generate a word line control signal based on a decoding result of the row decoder.

The first sub-word line driver 201 may receive the first word line driving signal PXID1, the complementary signal PXIB1 of the first word line driving signal PXID1, and a first word line enable signal NWEI1. The first sub-word line driver 201 may output the first driving voltage DV1 based on the first word line enable signal NWEI1 and the first word line driving signal PXID1. When a word line corresponding to the first sub-word line driver 201 is activated, the first driving voltage DV1 has the first boosting voltage VPP1 and has a first negative voltage after the access to the word line is terminated. Each of the first word line enable signal NWEI1 and a second word line enable signal NWEI2 may be generated by the row decoder. Each of the first word line enable signal NWEI1 and the second word line enable signal NWEI2 may be generated through a separate signal generator configured to generate a word line enable signal based on a decoding result of each row decoder.

The second sub-word line driver 211 may receive the second word line driving signal PXID2, the complementary signal PXIB2 of the second word line driving signal PXID2, and the second word line enable signal NWEI2. The second sub-word line driver 211 may output the second driving voltage DV2 based on the second word line enable signal NWEI2 and the second word line driving signal PXID2. When a word line corresponding to the second sub-word line driver 211 is activated, the second driving voltage DV2 has the second boosting voltage VPP2 and has a second negative voltage after the access to the word line is terminated.

The first sub-word line driver 201 and the second sub-word line driver 211 may respectively drive word lines of different stairs of the cell array structure CAS. For example, the first sub-word line driver 201 may drive a word line of a relatively lower stair, and the second sub-word line driver 211 may drive a word line of a relatively upper stair. Due to the stair structure of the cell array structure CAS, a conductive line of a relatively lower stair may have a large loading, and a conductive line of a relatively upper stair may have a small loading. Loading differences of conductive lines of a plurality of layers may cause the deterioration of operation of a three-dimensional integrated circuit memory device.

Sub-word line drivers of a three-dimensional integrated circuit memory device according to an embodiment may operate with different driving characteristics to equally drive the word lines of the cell array structure CAS. For example, when a first sub-word line driver drives a word line, the first boosting voltage VPP1 corresponding to the first driving voltage DV1 may be relatively higher than the second boosting voltage VPP2 corresponding to the second driving voltage DV2. The first sub-word line driver may apply a relatively high voltage to an electrode having a relatively large loading such that a delay or a lack of sensing margin caused when a word line is activated is compensated for.

Meanwhile, after the access to the word line is terminated, the first negative voltage among the first driving voltage DV1 may be relatively lower than the second negative voltage of the second driving voltage DV2. The first negative voltage whose level is relatively lower may compensate for a delay or a lack of sensing margin, which is caused when the word line is pulled down. In addition, the timing at which the first word line enable signal NWEI1 is applied to the first sub-word line driver 201 may be different from the timing at which the second word line enable signal NWEI2 is applied to the second sub-word line driver 211. For example, the timing at which the first word line enable signal NWEI1 is applied to the first sub-word line driver 201 may be relatively faster than the timing at which the second word line enable signal NWEI2 is applied to the second sub-word line driver 211. The delay due to the loading difference of conductive lines may be compensated for by advancing the timing at which the first word line enable signal NWEI1 is applied.

According to some embodiments, a channel width of a transistor belonging to the first sub-word line driver 201 may be different from a channel width of a transistor belonging to the second sub-word line driver 211. When the channel width of the transistor belonging to the first sub-word line driver 201 is larger than the channel width of the transistor belonging to the second sub-word line driver 211, the first sub-word line driver 201 may provide a relatively large current, and thus, a slope of a voltage change may be improved. As the first sub-word line driver 201 includes a transistor of a relatively large channel width, the delay and the lack of sensing margin due to the loading difference of conductive lines may be compensated for.

The peripheral circuit PERI may include a voltage generator which provides a voltage to be used in the sub-word line drivers 201 and 211 and the word line driving signal generators 203 and 213. For example, the voltage generator may provide various kinds of voltages such as the first boosting voltage VPP1, the second boosting voltage VPP2, the ground voltage VSS, a back bias voltage, and a negative voltage.

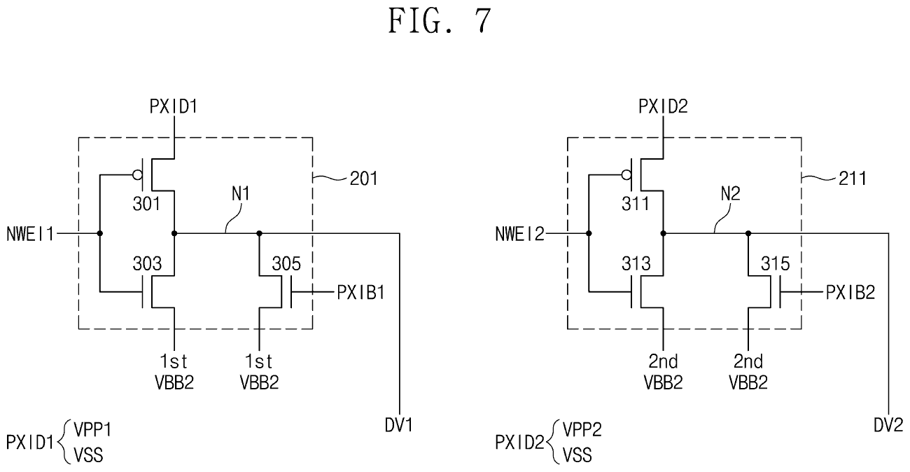

FIG. 7 is a circuit diagram of sub-word line drivers of a three-dimensional integrated circuit memory device according to an embodiment of the present disclosure. Referring to FIG. 7, the first sub-word line driver 201 may include a first pull-up transistor 301 providing the first word line driving signal PXID1 based on the first word line enable signal NWEI1, a first pull-down transistor 303 providing a first negative voltage 1st VBB2 based on the first word line enable signal NWEI1, and a first keeping transistor 305 providing the first negative voltage 1st VBB2 when the first sub-word line driver 201 is not selected.

The second sub-word line driver 211 may include a second pull-up transistor 311 providing the second word line driving signal PXID2 based on the second word line enable signal NWEI2, a second pull-down transistor 313 providing a second negative voltage 2nd VBB2 based on the second word line enable signal NWEI2, and a second keeping transistor 315 providing the second negative voltage 2nd VBB2 when the second sub-work line driver 211 not selected.

The first sub-word line driver 201 and the second sub-word line driver 211 may drive word lines associated with different stairs. For example, the first sub-word line driver 201 may drive a word line disposed in a relatively lower stair compared to a word line which the second sub-word line driver 211 drives. In this case, due to electrodes (or conductive lines) of the stair structure, the loading of the word line which the first sub-word line driver 201 drives may be larger than the loading of the word line which the second sub-word line driver 211 drives.

The first word line driving signal PXID1 may be applied to the first source/drain terminal of the first pull-up transistor 301, and the second word line driving signal PXID2 may be applied to the first source/drain terminal of the second pull-up transistor 311. The first word line driving signal PXID1 applied to the first source/drain terminal of the first pull-up transistor 301 may have the first boosting voltage VPP1 or the ground voltage VSS. The second word line driving signal PXID2 applied to the first source/drain terminal of the second pull-up transistor 311 may have the second boosting voltage VPP2 or the ground voltage VSS. In an embodiment, the first boosting voltage VPP1 may be relatively greater than the second boosting voltage VPP2. The second source/drain terminal of the first pull-up transistor 301 may be connected to the first source/drain terminal of the first pull-down transistor 303 at a node N1, and the second source/drain terminal of the second pull-up transistor 311 may be connected to the first source/drain terminal of the second pull-down transistor 313 at a node N2. The first word line enable signal NWEI1 may be applied to the gate terminal of the first pull-up transistor 301, and the second word line enable signal NWEI2 may be applied to the gate terminal of the second pull-up transistor 311. Depending on the first and second word line enable signals NWEI1 and NWEI2 respectively applied to the gate terminals of the first and second pull-up transistors 301 and 311, the voltages of the first and second word line driving signal PXID1 and PXID2 may be transferred to the nodes N1 and N2 or may be blocked.

The first negative voltage 1st VBB2 may be applied to the second source/drain terminal of the first pull-down transistor 303, and the second negative voltage 2nd VBB2 may be applied to the second source/drain terminal of the second pull-down transistor 313. The first word line enable signal NWEI1 may be applied to the gate terminal of the first pull-down transistor 303, and the second word line enable signal NWEI2 may be applied to the gate terminal of the second pull-down transistor 313. Depending on the first and second word line enable signals NWEI1 and NWEI2, the first and second pull-down transistors 303 and 313 may pull down the voltages of the nodes N1 and N2 to the first and second negative voltages 1st VBB2 and 2nd VBB2. In an embodiment, the first negative voltage 1st VBB2 may be relatively lower than the second negative voltage 2nd VBB2.

In addition, according to some embodiments, the timing at which the first word line enable signal NWEI1 is input to the gate terminals of the first pull-up transistor 301 and the first pull-down transistor 303 may be relatively faster than the timing at which the second word line enable signal NWEI2 is input to the gate terminals of the second pull-up transistor 311 and the second pull-down transistor 313.

First source/drain terminals of the first and second keeping transistors 305 and 315 may be connected to the nodes N1 and N2. The first negative voltage 1st VBB2 may be applied to the second source/drain terminal of the first keeping transistor 305, and the second negative voltage 2nd VBB2 may be provided to the second source/drain terminal of the second keeping transistor 315. The complementary signal PXIB1 of the first word line driving signal PXID1 may be applied to the gate terminal of the first keeping transistor 305, and the complementary signal PXIB2 of the second word line driving signal PXID2 may be applied to the gate terminal of the second keeping transistor 315. The first keeping transistor 305 may operate in response to the complementary signal PXIB1 and may keep a word line with a ground level when the corresponding word line is not selected, and the second keeping transistor 315 may operate in response to the complementary signal PXIB2 and may keep a word line with a ground level when the corresponding word line is not selected.

Meanwhile, the channel width of each of the first pull-up transistor 301, the first pull-down transistor 303, and the first keeping transistor 305 constituting the first sub-word line driver 201 may be larger than the channel width of each of the second pull-up transistor 311, the second pull-down transistor 313, and the second pull-down transistor 313 constituting the second sub-word line driver 211.

The first and second pull-up transistors 301 and 311 may be implemented with a PMOS transistor, and the first and second pull-down transistors 303 and 313 and the first and second keeping transistors 305 and 315 may be implemented with an NMOS transistor. However, this is provided as an example, and kinds of the transistors 301 to 315 may be variously changed or modified. Alternatively, the first and second keeping transistors 305 and 315 may be removed; in this case, the first and second pull-down transistors 303 and 313 may partially perform a role of a keeping transistor.

In some embodiments, the transistors 301, 303, and 305 constituting the first sub-word line driver 201 or the transistors 311, 313, and 315 constituting the second sub-word line driver 211 may have a planar transistor structure (e.g., a planar FET structure) in which one surface of a channel is in contact with a gate, a transistor structure (e.g., a finFET structure) in which two or more surfaces are in contact with a gate, a structure (e.g., a gate all around (GAA) in which all the surfaces surround a gate, or a multi-bridge channel structure (MBC FET).

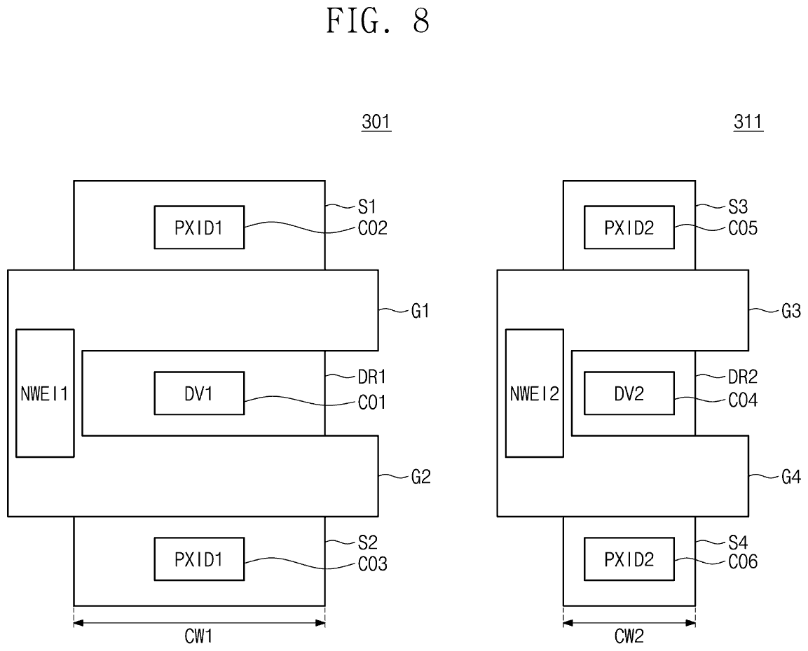

FIG. 8 is a diagram illustrating an example of pull-up transistors of a sub-word line driver according to an embodiment of the present disclosure. Referring to FIG. 8, the first pull-up transistor 301 may include a first gate G1, a second gate G2, a first source region S1, a second source region S2, and a first drain region DR1. The first word line enable signal NWEI1 may be applied to the first gate G1 and the second gate G2. Channels may be formed between the source regions S1 and S2 and the first drain region DR1, beneath the first gate G1 and the second gate G2. The first pull-up transistor 301 may have a first channel width CW1.

The second pull-up transistor 311 may include a third gate G3, a fourth gate G4, a third source region S3, a fourth source region S4, and a second drain region DR2. The second word line enable signal NWEI2 may be applied to the third gate G3 and the fourth gate G4. Channels may be formed between the source regions S3 and S4 and the second drain region DR2, beneath the third gate G3 and the fourth gate G4. The second word line driving signal PXID2 may be applied to contacts CO5 and CO6 respectively formed in the third source region S3 and the fourth source region S4. The second driving voltage DV2 may be output through a contact CO4 of the second drain region DR2. The second pull-up transistor 311 may have a second channel width CW2.

The first channel width CW1 may be larger than the second channel width CW2. A source-drain current of the first pull-up transistor 301 may be larger than a source-drain current of the second pull-up transistor 311. A current capability of the first pull-up transistor 301 may be relatively high, and a slope of a voltage applied to a word line may be improved. A delay or a lack of sensing margin due to the loading difference of conductive lines forming the stair structure of the cell array structure CAS may be compensated for.

The pull-up transistors 301 and 311 are illustrated in FIG. 8 as having a structure with the gates G1, G2, G3, and G4 of two arms, but this corresponds to an exemplary structure. The pull-up transistors 301 and 311 may be formed to have a single arm. The pull-up transistors 301 and 311 may be formed to have more arms. As well as the pull-up transistors 301 and 311, the remaining transistors may have different channel widths. For example, the channel width of a first pull-down transistor included in a first sub-word line driver may be larger than the channel width of a second pull-down transistor included in a second sub-word line driver.

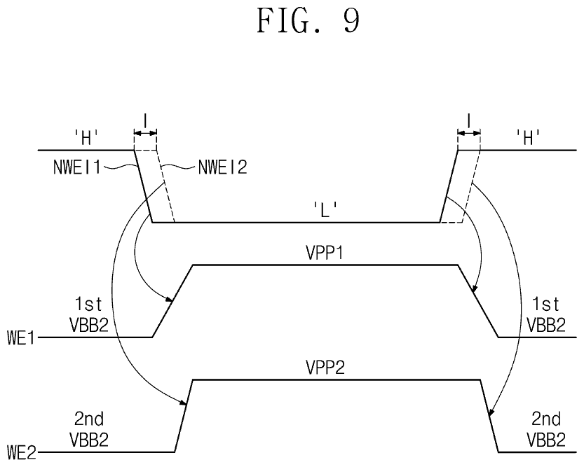

FIG. 9 is a timing diagram illustrating word line enable signals and voltages of electrodes of respective layers of a three-dimensional integrated circuit memory device according to an embodiment of the present disclosure. Referring to FIG. 9, the timing at which the first word line enable signal NWEI1 is activated may be relatively earlier than the timing at which the second word line enable signal NWEI2 is activated.

For example, in order to activate the corresponding word line, the first word line enable signal NWEI1 or the second word line enable signal NWEI2 is input to the first sub-word line driver 201 or the second sub-word line driver 211. The first sub-word line driver 201 may apply a driving voltage to the electrode WE1 with a relatively large loading, and the second sub-word line driver 211 may apply a driving voltage to the electrode WE2 with a relatively small loading. Due to the loading difference of the electrodes WE1 and WE2, slopes of voltages respectively applied to the electrodes WE1 and WE2 may be different. The slope of the electrode WE1 with a relatively large loading may be smaller than the slope of the electrode WE2 with a relatively small loading.

The timing at which the first word line enable signal NWEI1 is applied to the first sub-word line driver 201 may be faster than the timing at which the second word line enable signal NWEI2 is applied to the second sub-word line driver 211, as much as a time interval “I”. As the first word line enable signal NWEI1 is applied to be faster as much as the time interval “I”, the voltage of the electrode WE1 first starts to be boosted from the first negative voltage 1st VBB2 to the first boosting voltage VPP1. The voltage of the electrode WE2 is boosted from the second negative voltage 2nd VBB2 to the second boosting voltage VPP2 to be later as much as the time interval “I”. The electrode WE1 starts to be boosted to be faster as much as the time interval “I”; however, because the voltage slope of the electrode WE is relatively small, the voltage of the electrode WE1 is boosted slowly. The electrode WE2 starts to be boosted to be later as much as the time interval “I”; however, because the voltage slope of the electrode WE2 is relatively great, the voltage of the electrode WE2 is boosted fast. The time interval between the first word line enable signal NWEI1 and the second word line enable signal NWEI2 may compensate for the loading difference due to the stair structure which the electrodes of the cell array structure CAS form.

The time interval “I” between the first word line enable signal NWEI1 and the second word line enable signal NWEI2 may be adjusted through a delay circuit. A circuit (e.g., a row decoder, or a separate circuit generating a word line enable signal based on a decoding result of the row decoder) which generates the first word line enable signal NWEI1 and the second word line enable signal NWEI2 may include the delay circuit. Timings of the delay circuits respectively associated with the first word line enable signal NWEI1 and the second word line enable signal NWEI2 may be different. The delay circuit included in the row decoder may be configured such that the first word line enable signal NWEI1 is output to be earlier than the second word line enable signal NWEI2 as much as the time interval “I”.

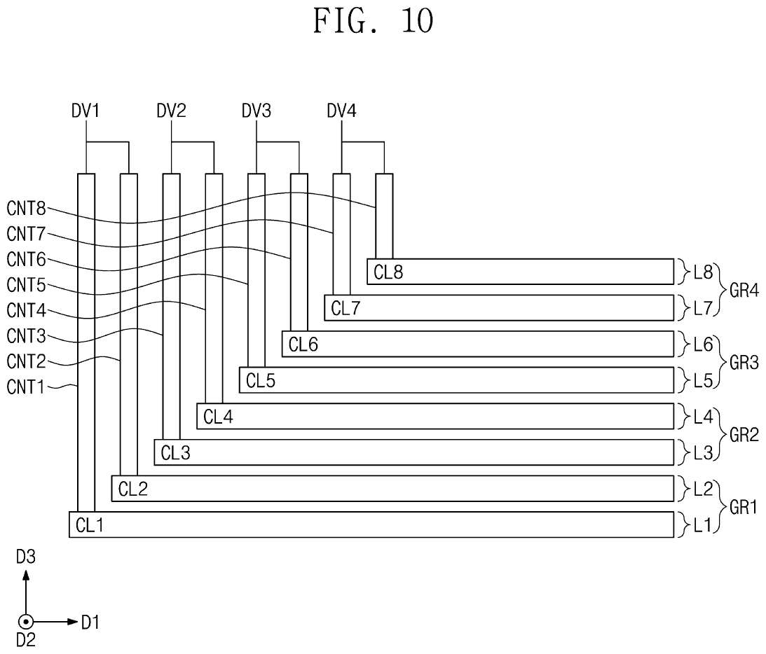

FIG. 10 is a diagram illustrating stacked conductive lines according to an embodiment of the present disclosure. Referring to FIG. 10, a plurality of layers L1, L2, . . . , L8 may be classified into groups GR1, GR2, . . . , GR4. The first layer L1 and the second layer L2 may be included in the group GR1, the third layer L3 and the fourth layer L4 may be included in the group GR2, the fifth layer L5 and the sixth layer L6 may be included in the group GR3, and the seventh layer L7 and the eighth layer L8 may be included in the group GR4. A first sub-word line driver may drive the group GR1 including the first layer L1 and the second layer L2 adjacent to the first layer L1. A second sub-word line driver may drive the group GR2 including the third layer L3 and the fourth layer L4 adjacent to the third layer L3.

Each of the plurality of layers L1 to L8 may include a corresponding conductive line. For example, the first layer L1 may include a conductive line CL1. The second layer L2 may include a conductive line CL2. The eighth layer L8 may include a conductive line CL8. The plurality of conductive lines CL1 to CL8 may form the stair structure together. In this case, a portion of the conductive line CL1 vertically overlaps the conductive line CL2, and the remaining portion thereof is opened in the third direction D3. A portion of the conductive line CL2 vertically overlaps the conductive line CL3, and the remaining portion thereof is opened in the third direction D3. A portion of the conductive line CL1, which is opened in the third direction D3, may be in contact with the contact CNT1. A portion of the conductive line CL2, which is opened in the third direction D3, may be in contact with the contact CNT2.

The same driving voltage may be applied to conductive lines included in the same group. For example, the driving voltage DV1 may be applied to the contact CNT1 and the contact CNT2. The driving voltage DV1 transferred through the contact CNT1 and the contact CNT2 is applied to the conductive lines CL1 and CL2 corresponding to the group GR1. The driving voltage DV2 is applied to the conductive lines CL3 and CL4 through the contact CNT3 and the contact CNT4.

Each of the conductive lines CL1 to CL8 corresponds to a word line included in each layer of the cell array structure CAS (refer to FIG. 4) and an electrode extending from the word line in a direction parallel to the first direction D1. Memory cells of the cell array structure CAS may be driven by the driving voltages DV1 to DV4 applied to the conductive lines CL1 to CL8. Memory cells included in the same group may be accessed simultaneously. For example, the memory cells included in the group GR1 may be accessed by the driving voltage DV1. The memory cells included in the group GR2 may be accessed by the driving voltage DV2.

A first sub-word line driver may apply the driving voltage DV1 to the conductive lines CL1 and CL2 corresponding to the group GR1. A second sub-word line driver may apply the driving voltage DV2 to the conductive lines CL3 and CL4 corresponding to the group GR2. The driving characteristics of the first sub-word line driver and the second sub-word line driver may be different depending on the corresponding groups. The first sub-word line driver drives the group GR1 corresponding to a relatively lower stair, and the second sub-word line driver drives the group GR2 corresponding to a relatively upper stair. The driving characteristic of the first sub-word line driver may be relatively higher than the driving characteristic of the second sub-word line driver. For example, a boosting voltage which the first sub-word line driver outputs to activate memory cells may be relatively greater than a boosting voltage which the second sub-word line driver outputs to activate memory cells. A negative voltage to which the first sub-word line driver pulls down a word line may be relatively lower than a negative voltage to which the second sub-word line driver pulls down a word line. A channel width of transistors constituting the first sub-word line driver may be larger than a channel width of transistors constituting the second sub-word line driver. The timing at which a word line enable signal is applied to the first sub-word line driver may be relatively earlier than the timing at which a word line enable signal is applied to the second sub-word line driver.

The plurality of layers L1 to L8 and the plurality of groups GR1 to GR4 are illustrated in FIG. 10 as an example. The number of stacked layers may increase or decrease, according to other embodiments.

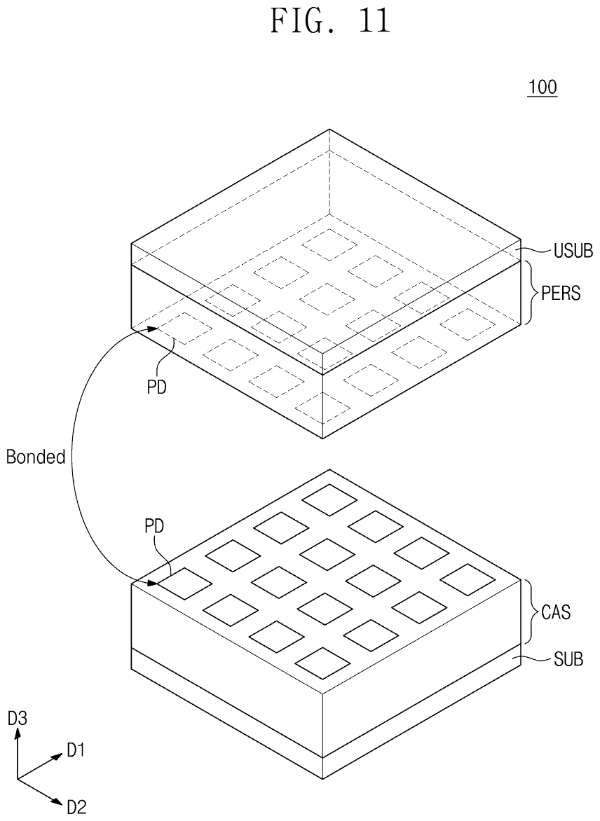

FIG. 11 is a perspective view of a three-dimensional integrated circuit memory device according to an embodiment of the present disclosure. Referring to FIG. 11, the cell array structure CAS may be formed on the substrate SUB.

A plurality of pads PD may be disposed at a surface of the cell array structure CAS. The plurality of pads PD may connect elements of the cell array structure CAS with the outside. The plurality of pads PD disposed on the surface of the cell array structure CAS may provide paths for various kinds of signals, various kinds of voltages, etc.

A peripheral circuit structure PERS may be formed on an upper substrate USUB. The peripheral circuit structure PERS may include various peripheral circuits for driving a cell array of the three-dimensional integrated circuit memory device 100. For example, the peripheral circuit structure PERS may include a row decoder, a column decoder, a control circuit, an input/output circuit, a sense amplifier circuit, a sub-word line driver, a voltage generator, etc. A plurality of pads PD may be disposed on a surface of the peripheral circuit structure PERS. The plurality of pads PD disposed on the surface of the peripheral circuit structure PERS may provide a signal path for a memory cell array of the cell array structure CAS.

The pads PD of the cell array structure CAS and the pads PD of the peripheral circuit structure PERS may be bonded to each other. For example, the pads PD of the cell array structure CAS and the pads PD of the peripheral circuit structure PERS may be bonded in a wafer bonding method. The peripheral circuit structure PERS and the cell array structure CAS of the three-dimensional integrated circuit memory device 100 may be bonded in the third direction D3. According to the above structure, the horizontal area of the three-dimensional integrated circuit memory device 100 may be reduced. Also, a signal path between the peripheral circuit and the memory cell array may be reduced, and thus, the performance of operation of the three-dimensional integrated circuit memory device 100 may be improved.

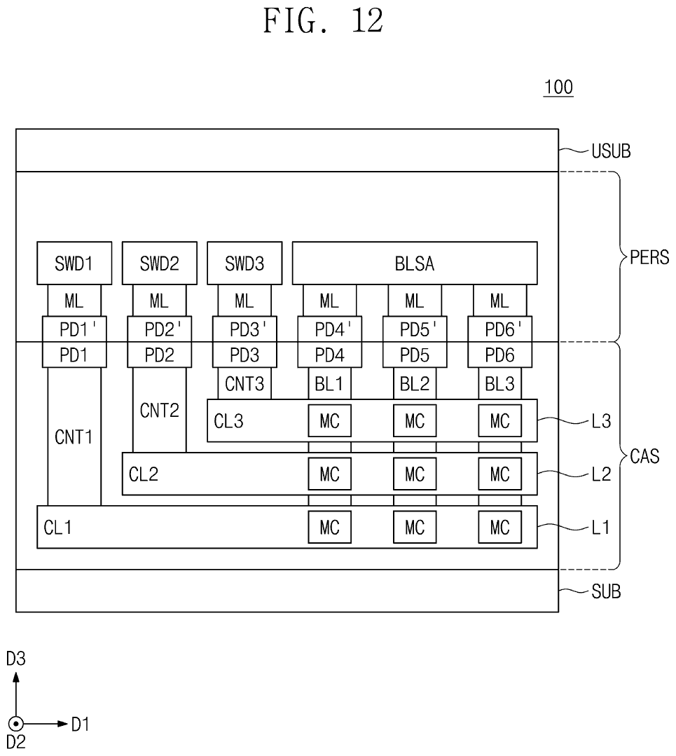

FIG. 12 is a diagram illustrating a wafer bonding structure according to an embodiment of the present disclosure. Referring to FIG. 12, the three-dimensional integrated circuit memory device 100 may include the substrate SUB and the upper substrate USUB. The cell array structure CAS may be formed on the substrate SUB. The cell array structure CAS may include the plurality of layers L1, L2, and L3. Each of the plurality of layers L1, L2, and L3 may include memory cells MC arranged to form one row and a conductive line connecting the memory cells MC. The conductive lines CL1, CL2, and CL3 may form the stair structure. A portion of the conductive line CL1 vertically overlaps the conductive line CL2, and the remaining portion thereof is opened in the third direction D3. A portion of the conductive line CL2 vertically overlaps the conductive line CL3, and the remaining portion thereof is opened in the third direction D3.

The conductive line CL1 and the contact CNT1 may be in contact with each other at the portion of the conductive line CL1, which is opened in the third direction D3. The conductive line CL2 and the contact CNT2 may be in contact with each other at the portion of the conductive line CL2, which is opened in the third direction D3. The conductive line CL3 may be in contact with the contact CNT3.

The plurality of contacts CNT1, CNT2, and CNT3 may extend in the third direction D3. The plurality of contacts CNT1, CNT2, and CNT3 may respectively be in contact with corresponding pads PD1, PD2, and PD3.

A plurality of bit lines BL1, BL2, and BL3 may extend in the third direction D3. Each of the plurality of bit lines BL1, BL2, and BL3 may be connected to the memory cells MC arranged in the third direction D3 to form one column. For example, the bit line BL1 may be connected to the memory cells MC of a first column, which are respectively included in the plurality of layers L1, L2, and L3. The bit line BL2 may be connected to the memory cells MC of a second column, which are respectively included in the plurality of layers L1, L2, and L3. The bit line BL3 may be connected to the memory cells MC of a third column, which are respectively included in the plurality of layers L1, L2, and L3. First ends of the plurality of bit lines BL1, BL2, and BL3 may respectively be in contact with corresponding pads PD4, PD5, and PD6.

The peripheral circuit structure PERS may be formed on the upper substrate USUB. The peripheral circuit structure PERS may include peripheral circuits for operations of the three-dimensional integrated circuit memory device 100. For example, the peripheral circuit structure PERS may include the first sub-word line driver SWD1, the second sub-word line driver SWD2, a third sub-word line driver SWD3, and a bit line sense amplifier circuit BLSA.

The first sub-word line driver SWD1 may be connected to a pad PD1′ through a metal line ML. The second sub-word line driver SWD2 may be connected to a pad PD2′ through a metal line ML. The third sub-word line driver SWD3 may be connected to a pad PD3′ through a metal line ML. The bit line sense amplifier circuit BLSA may be connected to a plurality of pads PD4′, PD5′, and PD6′ through metal lines ML.

The plurality of pads PD1 to PD6 disposed on the surface of the cell array structure CAS may be respectively bonded to the plurality of pads PD1′ to PD6 included in the peripheral circuit structure PERS. The first sub-word line driver SWD1 may apply the driving voltage to the conductive line CL1 through the metal line ML, the pad PD1′, the pad PD1, and the contact CNT1. The second sub-word line driver SWD2 may apply the driving voltage to the conductive line CL2 through the metal line ML, the pad PD2′, the pad PD2, and the contact CNT2. The bit line sense amplifier circuit BLSA may sense and amplify voltages of the plurality of bit lines BL1, BL2, and BL3 through the metal lines ML and the pads PD4′, PD5′, PD6′, PD4, PD5, and PD6.

The driving characteristic of the first sub-word line driver may be different from the driving characteristic of the second sub-word line driver. The driving characteristic of the first sub-word line driver may be better than the driving characteristic of the second sub-word line driver. For example, the boosting voltage which the first sub-word line driver SWD1 applies to the first conductive line CL1 may be relatively greater than the boosting voltage which the second sub-word line driver SWD2 applies to the conductive line CL2. The negative voltage to which the first sub-word line driver SWD1 pulls downs the conductive line CL1 may be lower than the negative voltage which the second sub-word line driver SWD2 pulls down the conductive line CL2. The timing at which the word line enable signal is applied to the first sub-word line driver SWD1 may be relatively faster than the timing at which the word line enable signal is applied to the second sub-word line driver SWD2. The channel width of transistors constituting the first sub-word line driver SWD1 may be larger than the channel width of transistors constituting the second sub-word line driver SWD2.

A three-dimensional integrated circuit memory device according to an embodiment of the present disclosure may have a structure in which a plurality of word lines are vertically stacked. Word lines or conductive lines constituting the word lines may form the stair structure. The loading of a word line corresponding to a relatively lower stair may be larger than the loading of a word line corresponding to a relatively upper stair. Sub-word line drivers of a three-dimensional integrated circuit memory device according to an embodiment of the present disclosure may have different driving characteristics depending on respective stairs. Accordingly, the deterioration of an operation speed and a sensing margin caused due to a loading difference of word lines may be compensated for, and the performance of the three-dimensional integrated circuit memory device may be improved.

A three-dimensional integrated circuit memory device according to an embodiment of the present disclosure may include a plurality of electrodes vertically stacked, a plurality of contacts each being in contact with an electrode in an open area and vertically extending, a plurality of sub-word line drivers driving word lines through the contacts. The sub-word line drivers may have different driving characteristics depending on stairs of the corresponding electrodes. Accordingly, elements belonging to different layers may be driven at the same speed. This may mean that the performance of the three-dimensional integrated circuit memory device is maintained.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A three-dimensional integrated circuit memory device, comprising:
a substrate having a plurality of layers vertically stacked thereon, said plurality of layers respectively including for each layer:
a plurality of memory cells horizontally arranged to form one row;
a word line electrically connected to the plurality of memory cells; and
an electrode horizontally extending from the word line and forming a stair structure with other electrodes associated with respective ones of the plurality of layers;
a plurality of vertically-extending contacts electrically contacting a corresponding plurality of electrodes in an open area of each of the plurality of layers;
a first sub-word line driver having a first driving characteristic, and electrically connected through a first one of the plurality of vertically-extending contacts to an electrode associated with a first layer among the plurality of layers; and
a second sub-word line driver having a second driving characteristic different from the first driving characteristic, and electrically connected through a second one of the plurality of vertically-extending contacts to an electrode associated with a second layer among the plurality of layers.

2. The device of claim 1, wherein the first layer among of the plurality of layers extends between the second layer among the plurality of layers and a surface of the substrate; wherein a vertical height of the first one of the plurality of vertically-extending contacts is greater than a vertical height of the second one of the plurality of vertically-extending contacts; and wherein the first driving characteristic associated with the first sub-word line driver is greater than the second driving characteristic associated with the second sub-word line driver.

3. The device of claim 2, further comprising:
a first driving signal generator configured to output a first boosting voltage to be applied to the first sub-word line driver; and
a second driving signal generator configured to output a second boosting voltage to be applied to the second sub-word line driver, and having a magnitude less than a magnitude of the first boosting voltage.

4. The device of claim 3,
wherein the first sub-word line driver includes:
a first pull-up transistor configured to pull-up a first output node to a first word line driving signal, in response to a first word line enable signal;
a first pull-down transistor configured to pull-down the first output node to a first negative voltage, in response to the first word line enable signal; and
a first keeping transistor configured to drive the first output node with a ground voltage when the first sub-word line driver is not selected; and
wherein the second sub-word line driver includes:
a second pull-up transistor configured to pull-up a second output node to a second word line driving signal, in response to a second word line enable signal;
a second pull-down transistor configured to pull-down the second output node to a second negative voltage, in response to the second word line enable signal; and
a second keeping transistor configured to drive the second output node with a ground voltage when the second sub-word line driver is not selected.

5. The device of claim 4, wherein the first negative voltage is lower than the second negative voltage.

6. The device of claim 4, wherein a channel width of the first pull-up transistor is larger than a channel width of the second pull-up transistor.

7. The device of claim 4, wherein a timing of a leading edge of the first word line enable signal is relatively earlier than a timing of leading edge of the second word line enable signal.

8. The device of claim 1, wherein transistors constituting the first sub-word line driver and the second sub-word line driver are implemented as planar MOSFETS, finFETs, or MBCFETs.

9. The device of claim 1,
wherein the first sub-word line driver is configured to drive a first group including the first layer and one or more layers adjacent to the first layer; and
wherein the second sub-word line driver is configured to drive a second group at including the second layer and one or more layers adjacent to the second layer.

10. The device of claim 1, wherein the first and second sub-word line drivers are provided with a second substrate, which is bonded to the substrate.

11. A three-dimensional integrated circuit memory device, comprising:
a first substrate;
a cell array structure including a plurality of layers vertically stacked on the first substrate;
a second substrate bonded to the first substrate; and
a peripheral circuit structure extending on the second substrate and including a plurality of sub-word line drivers, which are configured to drive word lines included in the cell array structure; and
wherein a first driving characteristic of a first sub-word line driver, which is configured to drive a first layer from among the plurality of sub-word line drivers, is different from a second driving characteristic of a second sub-word line driver, which is configured to drive a second layer from among the plurality of sub-word line drivers.

12. The device of claim 11, wherein the first layer is a layer below than the second layer; and wherein the first driving characteristic is greater than the second driving characteristic.

13. The device of claim 12, wherein the peripheral circuit structure further includes:
a voltage generator configured to generate a first boosting voltage and a first negative voltage, which are to be provided to the first sub-word line driver, and a second boosting voltage and a second negative voltage, which are to be provided to the second sub-word line driver.

14. The device of claim 13, wherein the first boosting voltage is higher than the second boosting voltage.

15. The device of claim 13, wherein the first negative voltage is lower than the second negative voltage.

16. The device of claim 12, wherein channel widths of transistors constituting the first sub-word line driver are larger than channel widths of transistors constituting the second sub-word line driver.

17. The device of claim 12, wherein a timing at which a leading edge of a first word line enable signal is applied to the first sub-word line driver is earlier than a timing at which a leading edge of a second word line enable signal is applied to the second sub-word line driver.

18. The device of claim 12, wherein the first sub-word line driver drives a first group including the first layer and one or more layers adjacent to the first layer; and wherein the second sub-word line driver drives a second group including the second layer and one or more layers adjacent to the second layer.

19. A three-dimensional integrated circuit memory device, comprising:
a stacked structure including a plurality of layers vertically stacked, wherein each of the plurality of layers includes:
memory cells disposed along a first direction of a horizontal direction and arranged in a second direction of a horizontal direction perpendicular to the first direction to form one row; and
a conductive line extending in the second direction, connected to gate terminals of the memory cells belonging to the one row, the conductive lines of the plurality of layers forming a stair structure;
a plurality of bit lines extending from one side of the stacked structure in a third direction of a vertical direction and each connected to source terminals of memory cells arranged in the third direction to form one column;
an electrode plate disposed on an opposite side of the stacked structure in the shape of a vertical plane and connected to cell capacitors of memory cells included in each of the plurality of layers;
a plurality of contacts each being in contact with a corresponding conductive line in an open area of each of the plurality of layers; and
a plurality of sub-word line drivers electrically connected to the contacts, and each configured to apply a driving voltage to a corresponding conductive line; and
wherein a first driving characteristic of a first sub-word line driver corresponding to a first layer among the plurality of layers is higher than a second driving characteristic of a second sub-word line driver corresponding to a second layer above the first layer.

20. The device of claim 19, wherein each of the first and second driving characteristics includes at least one of a boosting voltage, a negative voltage, a word line enable signal timing, and a channel width of a constituent transistor.
